(19) United States
(12) Patent Application Publication
(10) Pub. No.: US 2025/0120006 A1
(43) Pub. Date: Apr. 10, 2025

(54) PRINTED CIRCUIT BOARD

(71) Applicant: SAMSUNG ELECTRO-MECHANICS CO., LTD., Suwon-si (KR)

(72) Inventors: Dae Chul CHOI, Suwon-si (KR); Seung Bae LEE, Suwon-si (KR); Ye Ji KIM, Suwon-si (KR); Il Dong KIM, Suwon-si (KR); Woo Seok YANG, Suwon-si (KR); Ah Yeon IM, Suwon-si (KR); Kyoung Seok CHO, Suwon-si (KR); Jae Ho LEE, Suwon-si (KR)

(73) Assignee: SAMSUNG ELECTRO-MECHANICS CO., LTD., Suwon-si (KR)

(21) Appl. No.: 18/776,533

(22) Filed: Jul. 18, 2024

(30) Foreign Application Priority Data
Oct. 4, 2023 (KR) 10-2023-0131524

(51) Int. Cl. H05K 1/02; H01L 23/498; H01L 25/16; H05K 1/11; H05K 1/18

(52) U.S. Cl. CPC H05K 1/0233; H05K 1/115; H05K 1/185; H01L 23/49838; H01L 25/16; H05K 2201/086; H05K 2201/09827; H05K 2201/10522

(57) ABSTRACT

A printed circuit board includes a substrate; first and second through-portions penetrating between upper and lower surfaces of the substrate; a magnetic layer disposed in the first through-portion; a voltage regulator disposed in the second through-portion; a first through-hole penetrating between upper and lower surfaces of the magnetic layer; a first insulating layer disposed on the substrate, covering the magnetic layer and the voltage regulator, and filling the second through-portion and the first through-hole; a second through-hole penetrating between upper and lower surfaces of the first insulating layer in the first through-hole; a first wiring pattern disposed on an upper surface of the magnetic layer; a second wiring pattern disposed on a lower surface of the magnetic layer; and a first via pattern disposed in the second through-hole and connecting the first and second wiring patterns to each other.

### CROSS-REFERENCE TO RELATED APPLICATIONS

This application claims the benefit of priority to Korean Patent Application No. 10-2023-0131524 filed on Oct. 4, 2023 in the Korean Intellectual Property Office, the disclosure of which is incorporated herein by reference in its entirety.

### TECHNICAL FIELD

The present disclosure relates to a printed circuit board.

### BACKGROUND

Recently, to reduce a size of a semiconductor chip and to increase power efficiency, it may be necessary to embed various passive devices such as a capacitor and an inductor in a package substrate. In the case of an inductor, it may be necessary to improve inductance as compared to a general chip component by changing a material and a structure.

### SUMMARY

An aspect of the present disclosure is to provide a printed circuit board which may implement size reduction and may increase integration density.

An aspect of the present disclosure is to provide a printed circuit board which may increase power efficiency.

An aspect of the present disclosure is to provide a printed circuit board which may increase a noise reduction effect.

An aspect of the present disclosure is to embed a voltage regulator (VR) and a magnetic composite inductor (MCI) in a substrate. If desired, integrated passive devices (IPD) may be further embedded.

For example, according to an example embodiment, a printed circuit board includes a substrate; first and second through-portions penetrating between upper and lower surfaces of the substrate; a magnetic layer disposed in the first through-portion; a voltage regulator disposed in the second through-portion; a first through-hole penetrating between upper and lower surfaces of the magnetic layer; a first insulating layer disposed on the substrate, covering the magnetic layer and the voltage regulator, and filling the second through-portion and the first through-hole; a second through-hole penetrating between upper and lower surfaces of the first insulating layer in the first through-hole; a first wiring pattern disposed on an upper surface of the magnetic layer; a second wiring pattern disposed on a lower surface of the magnetic layer; and a first via pattern disposed in the second through-hole and connecting the first and second wiring patterns to each other.

An aspect of the present disclosure is to dispose a magnetic film in a through-portion of a substrate and to form an MCI on a magnetic film.

For example, according to an example embodiment, a printed circuit board includes a substrate having a through-portion; a magnetic layer spaced apart from the substrate in the through-portion and having a plurality of through-holes; an insulating layer covering the substrate and the magnetic layer, filling a space between a wall surface of the through-portion and a side surface of the magnetic layer, and filling each of the plurality of through-holes; a first wiring pattern layer disposed on an upper surface of the insulating layer; a second wiring pattern layer disposed on a lower surface of the insulating layer; and a plurality of via patterns penetrating the insulating layers, respectively, in the plurality of through-holes.

An aspect of the present disclosure is to dispose an MCI and an integrated circuit chip in substrate.

For example, according to an example embodiment, a printed circuit board includes a substrate having a first through-portion and a second through-portion spaced apart from each other; a magnetic layer disposed in the first through-portion; an inductor disposed in the magnetic layer, an integrated circuit chip disposed on the second through-portion; and an insulating layer disposed on the substrate and at least partially filling the first through-portion and the second through-portion. The inductor includes: a first wiring pattern disposed on an upper surface of the magnetic layer, a second wiring pattern disposed on a lower surface of the magnetic layer, pattern vias penetrating the magnetic layer and connecting the first and second wiring patterns to form the inductor.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 shows a block diagram illustrating an example of an electronic device system;

FIG. 2 shows a perspective diagram illustrating an example of an electronic device;

FIG. 3 shows a cross-sectional diagram illustrating an example of a printed circuit board;

FIG. 4 shows a plan cross-sectional diagram taken along line A-A′ in FIG. 3;

FIGS. 5A to 5E show cross-sectional diagrams illustrating an example of manufacturing the printed circuit board in FIG. 3;

FIG. 6 shows a cross-sectional diagram illustrating a modified example of a printed circuit board in FIG. 3;

FIG. 7 shows a plan cross-sectional diagram taken along line B-B′ in FIG. 6;

FIG. 8 shows a cross-sectional diagram illustrating another example of a printed circuit board;

FIG. 9 shows a plan cross-sectional diagram taken along line C-C′ in FIG. 8;

FIGS. 10A to 10E show cross-sectional diagrams illustrating processes of manufacturing the printed circuit board in FIG. 8;

FIG. 11 shows a cross-sectional diagram illustrating a modified example of the printed circuit board in FIG. 8;

FIG. 12 shows a plan cross-sectional diagram taken along line D-D′ in FIG. 11;

FIG. 13 shows a cross-sectional diagram illustrating an example of a coil portion; and

FIG. 14 shows a plan cross-sectional diagram illustrating various examples of a coil portion.

### DETAILED DESCRIPTION

Hereinafter, embodiments of the present disclosure will be described as follows with reference to the attached drawings.

### Electronic Device

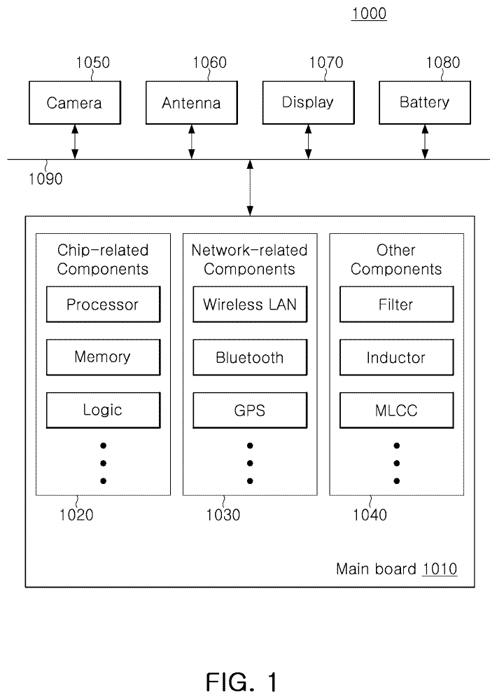

FIG. 1 is a block diagram illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

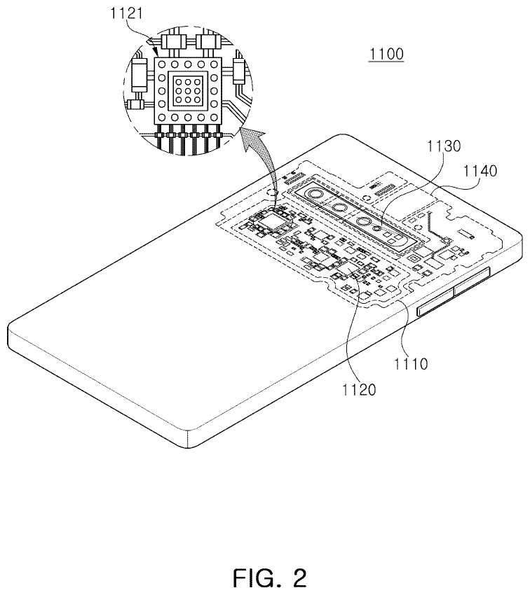

FIG. 2 is a perspective diagram illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

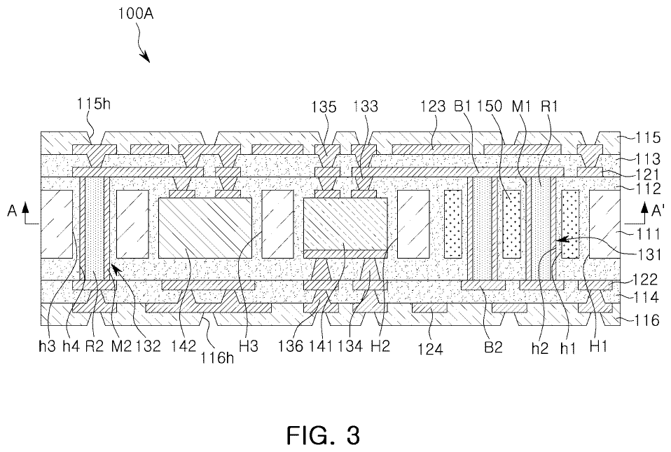

FIG. 3 is a cross-sectional diagram illustrating an example of a printed circuit board.

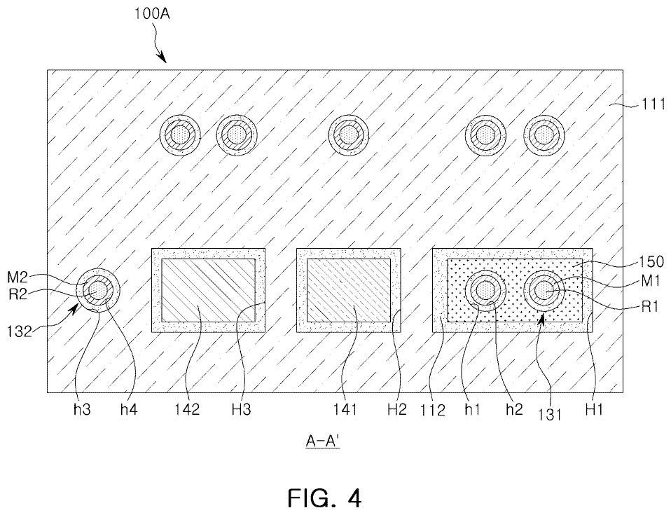

FIG. 4 is a plan cross-sectional diagram taken along line A-A′ in FIG. 3.

Referring to the drawing, a printed circuit board 100A according to the example may include a substrate 111, first and second through-portions H1 and H2 penetrating between upper and lower surfaces of the substrate 111, a magnetic layer 150 disposed in the first through-portion H1, a voltage regulator 141 disposed in the second through-portion H2, a first through-hole h1 penetrating between upper and lower surfaces of the magnetic layer 150, a first insulating layer 112 disposed on the substrate 111, covering the magnetic layer 150 and the voltage regulator 141, and filling the second through-portion H2 and the first through-hole h1, a second through-hole h2 penetrating between upper and lower surfaces of the first insulating layer 112 in the first through-hole h1, a first wiring pattern B1 disposed on an upper surface of the magnetic layer 150, a second wiring pattern B2 disposed on a lower surface of the magnetic layer 150, and a first via pattern M1 disposed in the second through-hole h2 and connecting the first and second wiring patterns B1 and B2 to each other. The inductor 131 may be disposed on the substrate 111 through the magnetic layer 150, and the first and second wiring patterns B1 and B2 and first via pattern M1 connected to each other to surround at least a portion of the magnetic layer 150. The first insulating layer 112 may be disposed between the first and second wiring patterns B1 and B2 and the upper and lower surfaces of the magnetic layer 150. The first via pattern M1 may be disposed on a wall surface of the second through-hole h2, and the inductor 131 may include a first filler R1 filling a space between the first via pattern M1 in the second through-hole h2.

As described above, in the printed circuit board 100A according to the example, the magnetic layer 150 and the voltage regulator 141 may be disposed and embedded in the first and second through-portions H1 and H2 of the substrate 111, respectively, which may be a core layer, and may form an MCI-type inductor 131 in the magnetic layer 150. For example, a structure in which the inductor 131 and the voltage regulator 141 are embedded together may be provided. Also, the magnetic layer 150 provided using a magnetic film may be spaced apart from a wall surface of the first through-portion H1, the first insulating layer 112 may fill the first through-portion H1, and the MCI type inductor 131 may be formed on the magnetic layer 150. Accordingly, slimming and integration may be increased, and power efficiency and noise reduction effects may also be increased. Also, the inductor 131 may be implemented by forming a first through-hole h1 in the magnetic layer 150, filling the hole with the first insulating layer 112, forming a second through-hole h2 with a diameter smaller than that of the first through-hole h1, and forming the first via pattern M1 by plating an internal side of the second through-hole h2, and accordingly, metal oxide included in the magnetic layer 150 may not be exposed to a surface, thereby preventing the magnetic layer 150 from dissolving into an acid solution during the manufacturing process.

The printed circuit board 100A according to the example may include a third through-hole h3 penetrating between upper and lower surfaces of the substrate 111 and filled with the first insulating layer 112, a fourth through-hole h4 penetrating between upper and lower surfaces of the first insulating layer 112 in the third through-hole h3, a first wiring layer 121 disposed on an upper surface of the first insulating layer 112 and including the first wiring pattern B1, a second wiring layer 122 disposed on a lower surface of the first insulating layer 112 and including the second wiring pattern B2, and a second via pattern M2 disposed in the fourth through-hole h4 and connecting the first and second wiring layers 121 and 122 to each other. For example, the through-via 132 may be further included. The second via pattern M2 may be disposed on a wall surface of the fourth through-hole h4, and the through-via 132 may include a second filler R2 filling a space between the second via patterns M2 in the fourth through-hole h4. For example, the first and second wiring layers 121 and 122 may be disposed on upper and lower surfaces of the first insulating layer 112, such that various wiring designs may be implemented. Also, as a material of the substrate 111, various materials such as metal, glass, and silicon may be used in addition to an organic insulating material. Also, when the inductor 131 is formed, a through-via 132 for connection between the first and second wiring layers 121 and 122 may be formed together, and accordingly, a process may be simplified and cost and time may be reduced.

The printed circuit board 100A according to an example may further include a third through-portion h3 penetrating between upper and lower surfaces of the substrate 111, and a passive device 142 disposed on the third through-portion h3. The first insulating layer 112 may cover a passive device 142 and may fill the third through-portion h3. For example, in addition to the inductor 131 and the voltage regulator 141, a structure in which a passive device 142, such as an integrated passive device, is embedded together, may be provided, and accordingly, the noise reduction effect may be increased along with the increase of power efficiency described above. Also, the printed circuit board 100A according to an example may include a first via layer 133 including a connection via penetrating an upper side of the first insulating layer 112 and connecting the first wiring layer 121 to a connection pad of each of the voltage regulator 141 and the passive device 142, and a second via layer 134 including a connection via penetrating a lower side of the first insulating layer 112 and connecting the second wiring layer 122 to a back surface of the voltage regulator 141. For example, the voltage regulator 141, the passive device 142, and the inductor 131 may be electrically connected to each other through the first via layer 133 and the first wiring layer 121. Also, heat dissipation of the voltage regulator 141 may be implemented through the second via layer 134 and the second wiring layer 122.

The printed circuit board 100A according to the example may further include a second insulating layer 113 disposed on an upper surface of first insulating layer 112, a third insulating layer 114 disposed on a lower surface of first insulating layer 112, a third wiring layer 123 disposed on an upper surface of second insulating layer 113, a third via layer 135 including a connection via penetrating the fourth wiring layer 124 and the second insulating layer 113 disposed on a lower surface of the third insulating layer 114 and connecting the first and third wiring layers 121 and 123 to each other, a fourth via layer 136 including a connection via penetrating the third insulating layer 114 and connecting the second and fourth wiring layers 122 and 124 to each other, a first resist layer 115 disposed on an upper surface of the second insulating layer 113 and having a first opening 115h exposing the third wiring layer 123, and a second resist layer 116 disposed on a lower surface of the third insulating layer 114 and having a second opening 116h exposing the fourth wiring layer 124. For example, a form of a multilayer package substrate implemented through a build-up process may be obtained.

Hereinafter, the components of the printed circuit board 100A according to the example may be described in greater detail with reference to the drawings.

The substrate 111 may be configured as a core layer. For example, the substrate 111 may include an organic core layer, a glass core layer, a metal core layer, a silicon core layer, or a ceramic core layer. The organic core layer may include an organic insulating material. The organic core layer may include an organic insulating material. The organic insulating material may include a thermosetting resin such as an epoxy resin, a thermoplastic resin such as polyimide, or a material including an inorganic filler, an organic filler, and/or glass fiber (glass cloth, glass fabric) along with resin. For example, the organic insulating material may be a non-photosensitive insulating material such as copper clad laminate (CCL), Ajinomoto build-up film (ABF), or prepreg (PPG), but an example embodiment thereof is not limited thereto, and other polymer materials may be used. The glass core layer may include glass. Glass may include, for example, pure silicon dioxide (about 100% SiO2) soda lime glass, borosilicate glass, aluminosilicate glass, or the like. However, an example embodiment thereof is not limited thereto, and an alternative glass material, such as fluorine glass, phosphate glass, chalcogen glass, or the like, may also be used as a material for the glass layer. Also, other additives may be further included to form glass with specific physical properties. The additives may include calcium carbonate (e.g. lime) and sodium carbonate (e.g. soda), and also magnesium, calcium, manganese, aluminum, lead, boron, iron, chromium, potassium, sulfur and antimony, and carbonate and/or oxide of these elements and other elements. Glass may be distinguished from glass fiber described above. The metal core layer may include metal. The metal may include, for example, copper (Cu), Invar, or the like, but an example embodiment thereof is not limited thereto. The silicon core layer may include pure silicon (Si). If desired, the silicon core layer may include an oxide layer formed on silicon (Si). Also, a nitride layer formed on the oxide layer may be included. The oxide layer may include a silicon oxide film, and the nitride layer may include a silicon nitride film, but an example embodiment thereof is not limited thereto. The ceramic core layer may include ceramic material. A ceramic material may include, for example, alumina (Al₂0₃) aluminum nitride (AlN), silicon carbide (SiC), silicon nitride (Si₃N₄), or the like, but an example embodiment thereof is not limited thereto.

The first to third insulating layers 112, 113, and 114 may include an organic insulating material. As described above, the organic insulating material may include a thermosetting resin such as an epoxy resin, a thermoplastic resin such as polyimide, or a material including an inorganic filler, an organic filler, and/or glass fiber (glass cloth, glass fabric) along with resin. For example, the organic insulating material may be a non-photosensitive insulating material such as copper clad laminate (CCL), Ajinomoto build-up film (ABF), or prepreg (PPG), but an example embodiment thereof is not limited thereto, and other polymer materials may be used. The first to third insulating layers 112, 113, and 114 may include the same or different organic insulating materials. The first to third insulating layers 112, 113, and 114 may be configured as the plurality of layers, if desired.

The first and second resist layers 115 and 116 may include a liquid or film-type solder resist, but an example embodiment thereof is not limited thereto, and may include other an organic insulating material such as ABF. The first and second resist layers 115 and 116 may have first and second openings 115h and 116h, respectively. A plurality of the first and second opening 115h and 116h may be provided. The first and second openings 115h and 116h may be formed as solder mask defined (SMD) and/or non-solder mask defined (NSMD). The first and second openings 115h and 116h may expose the third and fourth wiring layers 123 and 124, respectively, and a surface treatment layer may be disposed on a surface of the exposed pattern. The surface treatment layer may be formed by electrolytic gold plating, electroless gold plating, organic solderability preservative (OSP) or electroless tin plating, electroless silver plating, electroless nickel plating/substituted gold plating, direct immersion gold (DIG) plating, hot air solder leveling (HASL), or the like, but an example embodiment thereof is not limited thereto.

The first to fourth wiring layers 121 and 122, 123, and 124 may include a metal layer. The metal layer may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but an example embodiment thereof is not limited thereto. Each of the first to fourth wiring layers 121 and 122, 123, and 124 may perform various functions depending on a design. For example, a signal pattern, a power pattern, a ground pattern, or the like, may be included. Each of these patterns may have various forms such as a line, a plane, and a pad. The first to fourth wiring layers 121 and 122, 123, and 124 may include a seed layer and a metal layer formed on the seed layer. The seed layer may be configured as an electroless metal layer (or chemical copper) and/or a sputtering layer, and the metal layer may be configured as an electrolytic metal layer (or electrical copper), but an example embodiment thereof is not limited thereto.

The first and second wiring patterns B1 and B2 and the first and second via patterns M1 and M2 may include a metal material. As described above, the metal layer may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but an example embodiment thereof is not limited thereto. The second via pattern M2 may perform various functions depending on a design. For example, a signal via pattern, a power via pattern, and a ground via pattern may be included. The first and second wiring patterns B1 and B2 and the first and second via patterns M1 and M2 may include a seed layer and a metal layer formed on the seed layer. The seed layer may be an electroless metal layer (or chemical copper) and/or a sputtering layer, and the metal layer may be an electrolytic metal layer (or electrical copper), but an example embodiment thereof is not limited thereto.

The first and second fillers R1 and R2 may include a plugging material. The plugging material may include an insulating ink including an insulating resin such as epoxy. However, an example embodiment thereof is not limited thereto, and if desired, conductive ink may be included. The first and second fillers R1 and R2 may be formed through the same process and may thus include the same material, but an example embodiment thereof is not limited thereto.

A plurality of the first and second through-holes h1 and h2 may be provided. For example, on a plane, the second through-holes h2 each having a smaller diameter may be formed in the first through-holes h1. Accordingly, a plurality of the first via pattern M1 formed in the second through-hole h2 may also be formed. As described above, the inductor 131 may include a plurality of the first via pattern M1, and a plurality of the first wiring pattern B1 and a plurality of the second wiring pattern B2, connected to the plurality of first via patterns M1, may be provided. The plurality of first and second wiring patterns B1 and B2 may be included in the first and second wiring pattern layers, respectively, and the first and second wiring pattern layers may be included in the first and second wiring layers 121 and 122, respectively.

A plurality of the third and fourth through-holes h3 and h4 may be formed. For example, on a plane, fourth through-holes h4 each having a smaller diameter may be formed the third through-holes h3. Accordingly, a plurality of the second via patterns M2 formed in the fourth through-holes h4 may also be provided. As described above, a plurality of the through-vias 132 may be formed.

Each of the first to fourth via layers 133, 134, 135, and 136 may include a metal material. As described above, the metal material may include copper (Cu), aluminum (Al), silver (Ag), tin (Sn), gold (Au), nickel (Ni), lead (Pb), titanium (Ti), and/or alloys thereof, or the like. Preferably, copper (Cu) may be included, but an example embodiment thereof is not limited thereto. Each of the first to fourth via layers 133, 134, 135, and 136 may include a filed via filling a via hole, or may also include a conformal via disposed along a wall surface of the via hole. The first to fourth via layers 133, 134, 135, and 136 may perform various functions depending on a design. For example, a ground via, a power via, and a signal via may be included. The first and second via layers 133 and 134 may include connection vias tapered in opposite directions. The third and fourth via layers 135 and 136 may include connection vias tapered in opposite directions. The first to fourth via layers 133, 134, 135, and 136 may include an electroless plating layer (or chemical copper) and an electrolytic plating layer (or electric copper), respectively. A sputtering layer may be included instead of an electroless plating layer (or chemical copper), or, if desired, both may be included.

The voltage regulator 141 may include a circuit for adjusting a voltage. The voltage regulator 141 may be configured as a chip-type electronic component. For example, the voltage regulator 141 may be configured in the form of a semiconductor chip, and more specifically, may be configured as an integrated circuit (IC) die in which hundreds to millions of elements are integrated into a chip. The integrated circuit die may be formed based on an active wafer, and in this case, silicon (Si), germanium (Ge), gallium arsenide (GaAs) may be used as a base material for each body. Various circuits may be formed in the body. A connection pad may be formed on a front surface of the body, and the connection pad may include a conductive material such as aluminum (A1) or copper (Cu). If desired, a connection pad may also be formed on a back surface of the body. If desired, a plurality of voltage regulators 141 may be provided, and the plurality of voltage regulators 141 may be disposed together in the second through-portion H2, or a plurality of second through-portion H2 may be formed and the plurality of voltage regulators 141 may be disposed therein, respectively.

The passive device 142 may be configured as a chip-type electronic component including a resistor, a capacitor, an inductor, an impedance matching component, or a combination thereof. For example, the passive device 142 may be configured as integrated passive devices (IPD), and the integrated passive devices (IPD) may also be referred to as integrated passive components (IPC) or embedded passive components (EPC). If desired, a plurality of passive devices 142 may be provided, and the plurality of passive devices 142 may be disposed together in the third through-portion h3, or a plurality of third through-portions h3 may be formed and the plurality of passive devices 142 may be disposed therein, respectively.

The magnetic layer 150 may include a magnetic material. The magnetic material may include, for example, ferrite-based material, permalloy-based material, or the like. For example, Ni-based ferrite, Ni—Zn-based ferrite, Ni—Zn—Cu-based ferrite, Fe—Si—Al (Sendust), Ni—Mo—Fe (MPP: molypermalloy powder core), Ni—Fe (high flux core), or the like, may be included but an example embodiment thereof is not limited thereto, and may also include other generally used materials, such as a ferrite material or a permalloy-based material. Also, various types of magnetic materials including other magnetic powder may be used. The magnetic material may be used as paste or a composition to fill the first through-portion H1 and may be cured to form the magnetic layer 150. Accordingly, the magnetic layer 150 may be in contact with a wall surface of the first through-portion H1. For example, the magnetic layer 150 may be in contact with the substrate 111.

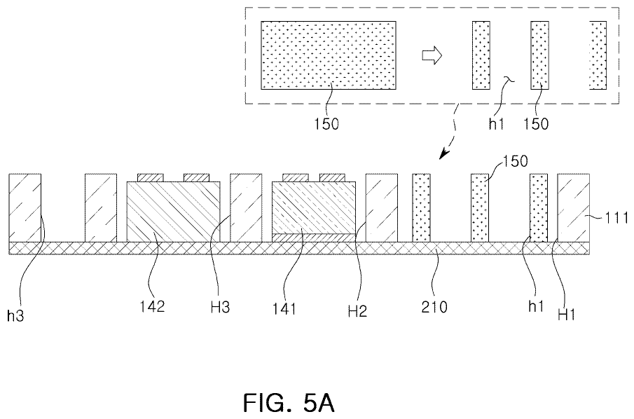

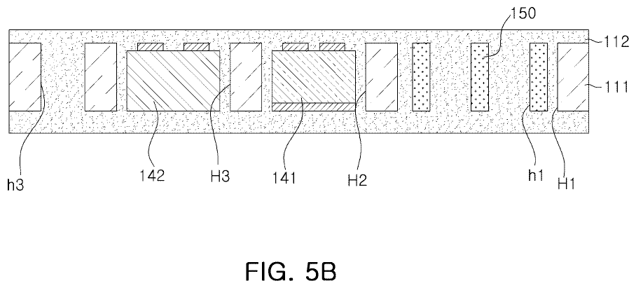

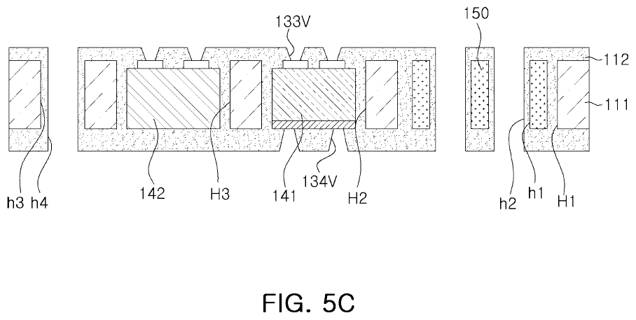

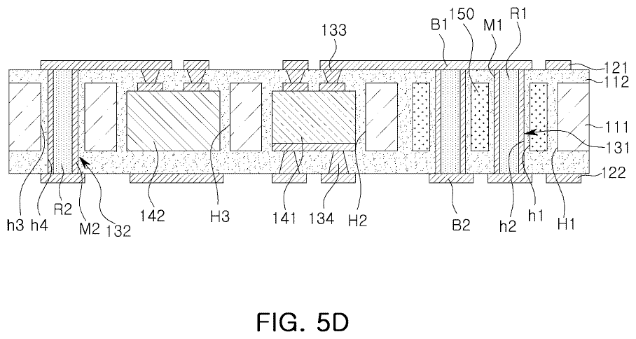

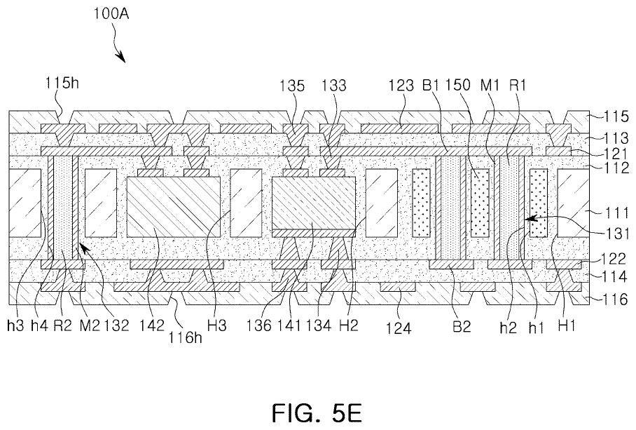

FIGS. 5A to 5E are cross-sectional diagrams illustrating an example of manufacturing the printed circuit board in FIG. 3.

Referring to FIG. 5A, first to third through-portions H1, H2, and H3 and a third through-hole h3 may be formed on the substrate 111. The first to third through-portion H1, H2, and H3 and the third through-hole h3 may be formed by various methods such as laser drilling, mechanical drilling, chemical etching, and blasting process, depending on the material of the substrate 111. Also, the first through-hole hl may be formed through the magnetic layer 150 in the form of a magnetic film or sheet using a mechanical drill, may be cut to an appropriate size, and may be disposed in the first through-portion H1. Also, the voltage regulator 141 and the passive device 142 may be disposed in the second and third through-portions H2 and H3, respectively. The magnetic layer 150, the voltage regulator 141, and the passive device 142 may be disposed using a tape 210.

Referring to FIG. 5B, the first insulating layer 112 may be laminated using a lamination process such as PPG or ABF, may cover the substrate 111, the magnetic layer 150, the voltage regulator 141, and the passive device 142, and may fill the first to third through-portion H1, H2, and H3 and the first and third through-hole h1 and h3. Thereafter, if desired, the laminate may be cut into a unit size through a trimming process.

Referring to FIG. 5C, thereafter, the second and fourth through-holes h2 and h4 may be formed in the first and third through-holes h1 and h3 using a mechanical drill. Also, the first and second via holes 133V and 134V for forming the first and second via layers 133 and 134 may be formed in the first insulating layer 112 through laser processing.

Referring to FIG. 5D, through the plating process and the plugging process, first and second via patterns M1 and M2, first and second fillers R1 and R2, first and second wiring patterns B1 and B2, first and second wiring layer 121 and 122 and first and second via layers 133 and 134 may be formed. For example, the inductor 131 and the through-via 132 may be formed. More specifically, the inductor 131 and the through-via 132 may be formed, for example, by forming a plating layer on upper and lower surfaces of the first insulating layer 112 and wall surfaces of the second and fourth through-holes h2 and h4 through a plating process, thereafter, filling the second and fourth through-holes h2 and h4 with a plugging material through the plugging process, and thereafter, removing the plating layer and a plugging material on upper and lower surfaces of the first insulating layer 112 through a flattening process, and thereafter, forming a plating layer through a plating process on upper and lower surfaces of the first insulating layer 112. In this process, the first and second wiring layers 121 and 122 and the first and second via layers 133 and 134 may also be formed. In the plating process, a plating layer patterned according to a design using a dry film exposure and development process. Also, through the planarization process, upper and lower surfaces of the first insulating layer 112 may be coplanar with each other, and an approximate interlayer boundary may be formed between the plating layers.

Referring to FIG. 5E, through a build-up process, required number of the second and third insulating layers 113 and 114, the third and fourth wiring layers 123 and 124, and the third and fourth via layers 135 and 136 may be formed, and the first and second resist layers 115 and 116 may be formed. Also, the first and second openings 115h and 116h may be formed in the first and second resist layers 115 and 116, respectively. The second and third insulating layers 113 and 114 may be formed using the above-described lamination process, the third and fourth wiring layers 123 and 124 and the third and fourth via layers 135 and 136 may be formed using the above-described plating process, and the first and second resist layers 115 and 116 may be formed through a lamination process or a liquid material coating process.

The printed circuit board 100A according to the above-described example may be manufactured through a series of processes, and other descriptions may be substantially the same as the descriptions described above.

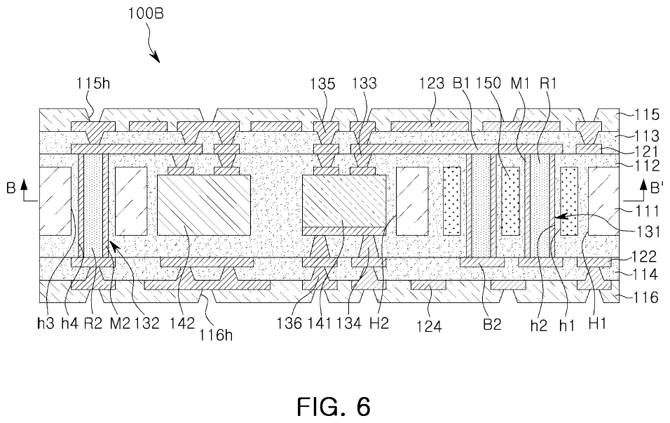

FIG. 6 is a cross-sectional diagram illustrating a modified example of a printed circuit board in FIG. 3.

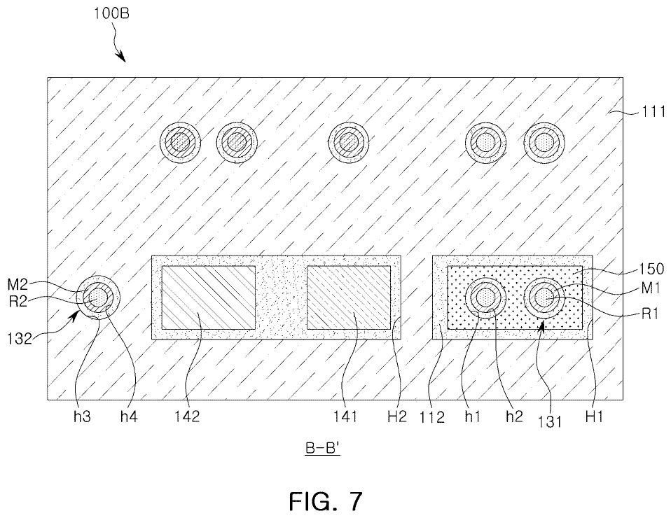

FIG. 7 is a plan cross-sectional diagram taken along line B-B′ in FIG. 6.

Referring to the drawing, in a printed circuit board 100B according to a modified example, in a printed circuit board 100A according to the aforementioned example, the third through-portion H3 may not be provided, and the second through-portion H2 may include passive device 142 may be disposed together with the voltage regulator 141. As described above, if desired, the component may be embedded by forming only a through-portion. The other descriptions may be substantially the same as the descriptions of the printed circuit board 100A according to the aforementioned example. The printed circuit board 100B according to the modified example may be manufactured by forming the second through-portion H2 in a larger size without the third through-portion H3 in the process of manufacturing the printed circuit board 100A according to the aforementioned example, and the detailed description thereof may not be provided.

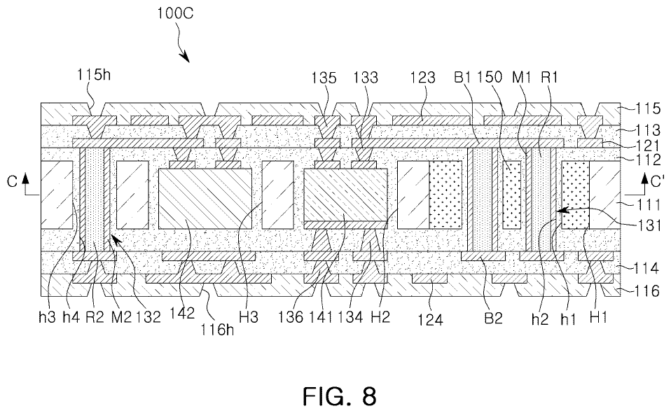

FIG. 8 is a cross-sectional diagram illustrating another example of a printed circuit board.

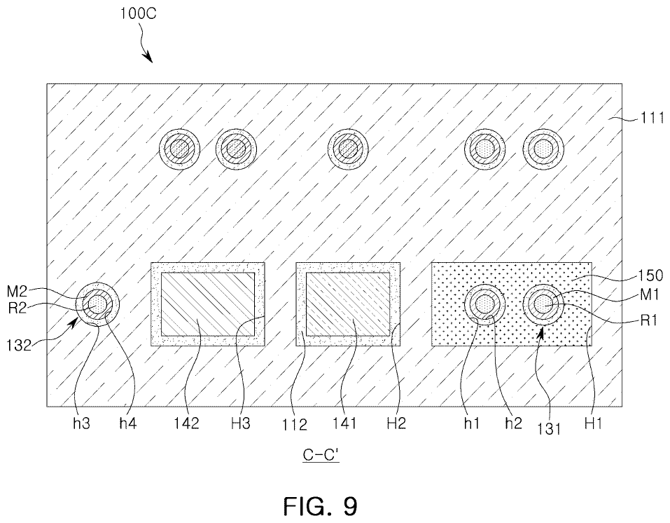

FIG. 9 is a plan cross-sectional diagram taken along line C-C′ in FIG. 8.

Referring to the drawings, in a printed circuit board 100C according to another example, in the printed circuit board 100A according to the aforementioned example, the magnetic layer 150 may be in contact with a wall surface of the first through-portion H1. For example, the magnetic layer 150 may be in contact with the substrate 111. Accordingly, the first insulating layer 112 may not fill the first through-portion H1. For example, in the magnetic layer 150, the first through-portion H1 may be filled with a paste or composition type rather than a film or sheet type material, and may be cured such that the magnetic layer 150 may be formed. As described above, if desired, the magnetic layer 150 may fill the first through-portion H1. The other descriptions may be substantially the same as the descriptions of the printed circuit board 100A according to the aforementioned example, and accordingly, overlapping descriptions may not be provided.

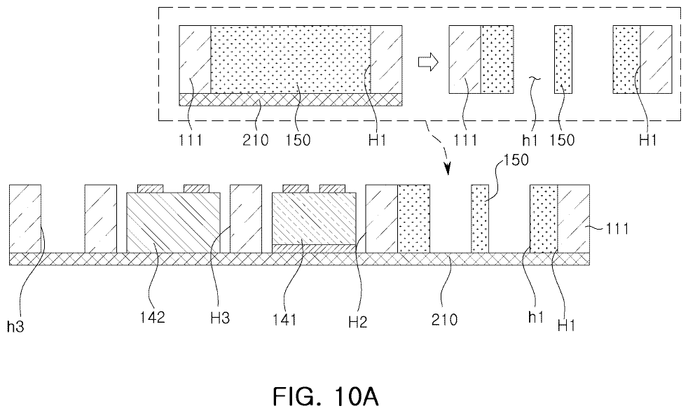

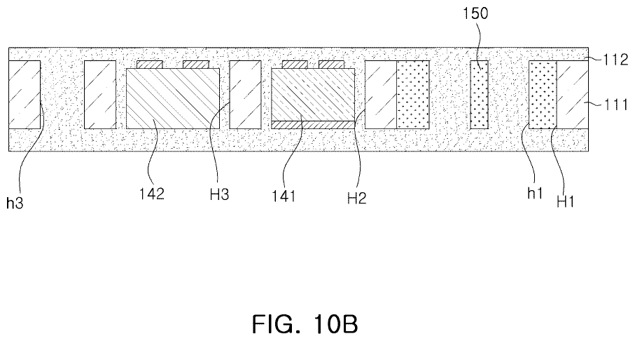

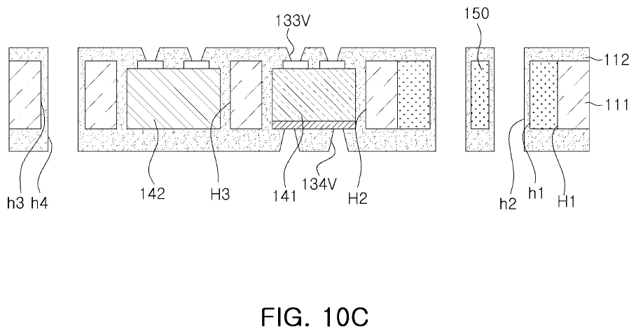

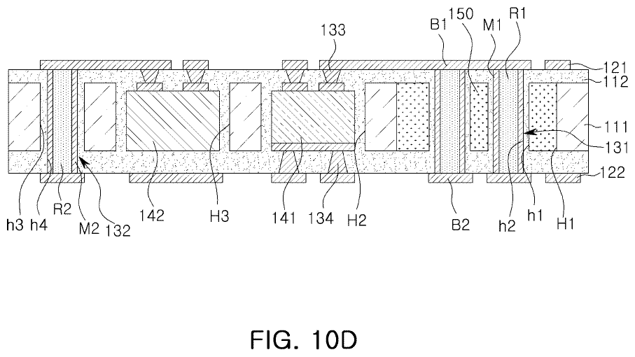

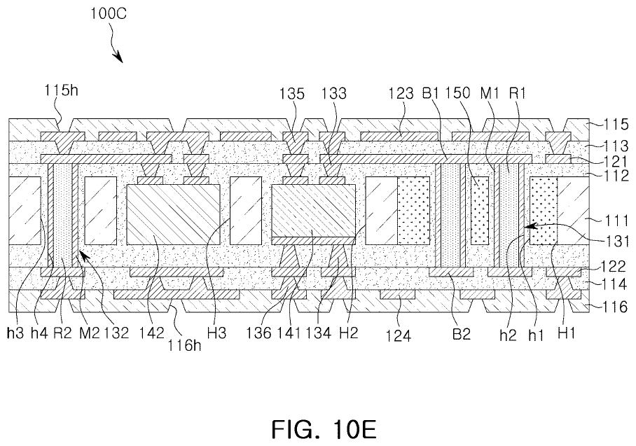

FIGS. 10A to 10E are cross-sectional diagrams illustrating processes of manufacturing the printed circuit board in FIG. 8.

Referring to FIG. 10A, first to third through-portions H1, H2, and H3 and third through-hole h3 may be formed on a substrate 111. The first to third through-portion H1, H2, and H3 and the third through-hole h3 may be formed by various methods such as laser drilling, mechanical drilling, chemical etching, and blasting process, depending on a material of the substrate 111. Also, the first through-portion H1 may be filled with magnetic paste or a magnetic composition and may be cured such that a magnetic layer 150 disposed on the first through-portion H1 may be formed. Thereafter, the first through-hole h1 may be formed on the magnetic layer 150 using a mechanical drill. Also, the voltage regulator 141 and the passive device 142 may be disposed in the second and third through-portions H2 and H3, respectively. A tape 210 may be used to form the magnetic layer 150 and to dispose the voltage regulator 141 and the passive device 142.

Referring to FIG. 10B, the substrate 111, magnetic layer 150, voltage regulator 141, and passive device 142 may be covered by laminating the first insulating layer 112 using a lamination process such as PPG or ABF, and the first to third through-portion H1, H2, and H3 and the first and third through-hole h1 and h3 may be filled. Thereafter, if desired, the laminate may be cut into a unit size through a trimming process.

Referring to FIG. 10C, thereafter, the second and fourth through-holes h2 and h4 may be formed in the first and third through-holes h1 and h3 using a mechanical drill. Also, first and second via holes 133V and 134V for forming first and second via layers 133 and 134 may be formed in the first insulating layer 112 through laser processing.

Referring to FIG. 10D, through the plating process and plugging process, first and second via patterns M1 and M2, first and second fillers R1 and R2, first and second wiring patterns B1 and B2, first and second wiring layer 121 and 122 and first and second via layers 133 and 134 may be formed. For example, an inductor 131 and a through-via 132 may be formed. More specifically, the inductor 131 and the through-via 132, for example, may be formed by forming a plating layer through a plating process on upper and lower surfaces of the first insulating layer 112 and wall surfaces of the second and fourth through-holes h2 and h4, thereafter, filling the second and fourth through-holes h2 and h4 with a plugging material through a plugging process, removing the plating layer and a plugging material on the upper and lower surfaces of the first insulating layer 112 through a flattening process, and forming a plating layer again through a plating process on upper and lower surfaces of the first insulating layer 112. In this process, the first and second wiring layers 121 and 122 and the first and second via layers 133 and 134 may also be formed. In the plating process, a plating layer patterned according to a design may be formed using a dry film exposure and development process. Also, due to the planarization process, upper and lower surfaces of the first insulating layer 112 may be coplanar with each other, and a boundary may be formed between the plating layers.

Referring to FIG. 10E, through a build-up process, the required number of the second and third insulating layers 113 and 114, the third and fourth wiring layers 123 and 124, and the third and fourth via layers 135 and 136 may be formed, and the first and second resist layers 115 and 116 may be formed. Also, the first and second openings 115h and 116h may be formed in the first and second resist layers 115 and 116, respectively. The second and third insulating layers 113 and 114 may be formed using the above-described lamination process, the third and fourth wiring layers 123 and 124 and the third and fourth via layers 135 and 136 may be formed using the above-described plating process, and the first and second resist layers 115 and 116 may be formed through a lamination process or a liquid material coating process.

The printed circuit board 100C according to another example described above may be manufactured through a series of processes, and other descriptions may be substantially the same as the descriptions described above.

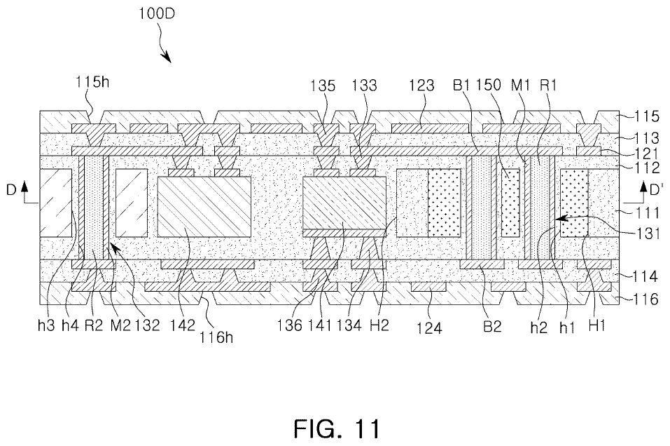

FIG. 11 is a cross-sectional diagram illustrating a modified example of the printed circuit board in FIG. 8.

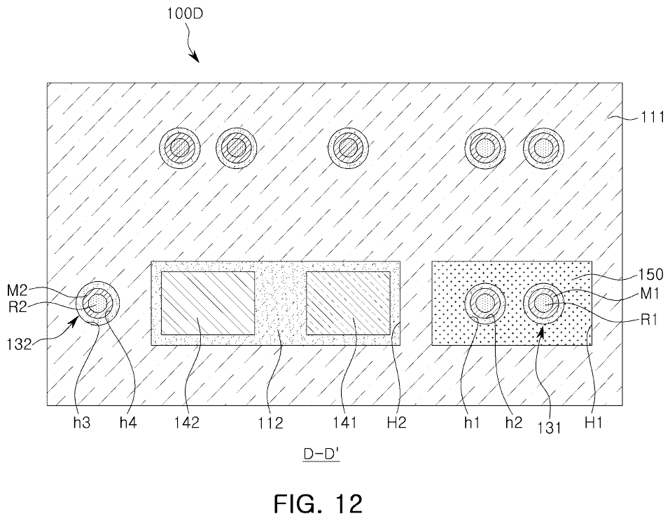

FIG. 12 is a plan cross-sectional diagram taken along line D-D′ in FIG. 11.

Referring to the drawing, in a printed circuit board 100D according to the modified example, the third through-portion h3 may not be provided in the printed circuit board 100B according to the other example described above, and a passive device may be disposed along with a voltage regulator 141 in the second through-portion H2. As described above, if desired, the component may be embedded by forming a through-portion. Other descriptions may be substantially the same as the descriptions of the printed circuit board 100A according to the aforementioned example and the printed circuit board 100C according to another example. The printed circuit board 100D according to the modified example may be manufactured by forming the second through-portion H2 in a larger size without the third through-portion H3 in the process of manufacturing the printed circuit board 100C according to the other example described above, and the detailed description may not be provided.

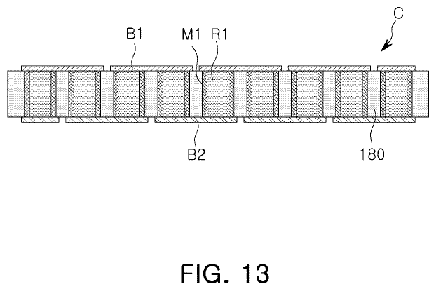

FIG. 13 is a cross-sectional diagram illustrating an example of a coil portion.

Referring to the drawings, the inductor 131 included in the above-described printed circuit boards 100A, 100B, 100C, and 100D may include one or more coil portions C, and in the coil portion C, a plurality of first and second wiring patterns B1 and B2 formed in body 180 and a plurality of first via pattern M1 may be alternately connected to each other. For example, in a cross-section, the coil portion C may have a coil structure connected by the required number of second wiring pattern B2, first via pattern M1, first wiring pattern B1, first via pattern M1, second wiring pattern B2, first via pattern M1, first wiring pattern B1, and first via pattern M1 and vertically alternatively formed. The body 180 may include the magnetic layer 150 and the first insulating layer 112 described above. Also, a first filler R1 may be filled in each of through-holes in which the first via pattern M1 is formed. As described above, the coil portion C may have a structure in which the number of coils surrounding the magnetic layer 150 may be increased, for example, a daisy chain shape which may increase inductance. Other descriptions may be substantially the same as the descriptions of the aforementioned printed circuit boards 100A, 100B, 100C, and 100D, and accordingly, overlapping descriptions may not be provided.

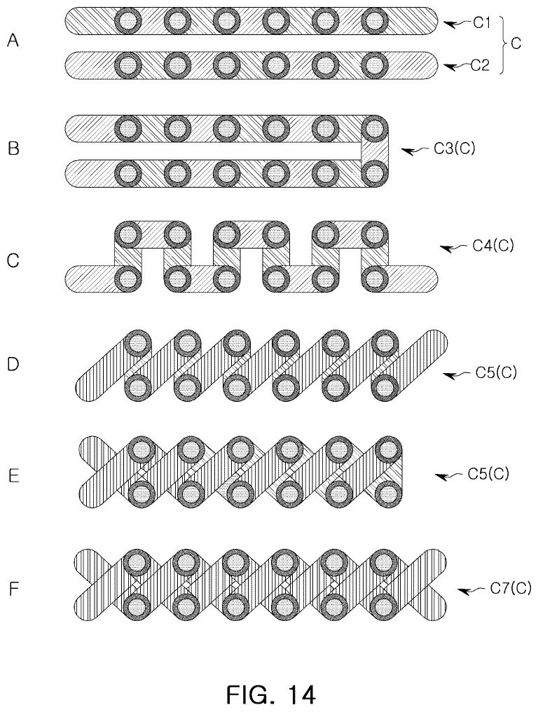

FIG. 14 is a plan cross-sectional diagram illustrating various examples of a coil portion.

Referring to the drawings, the coil portion C described above may have various shapes on a plane. For example, as in A, a plurality of coils C1 and C2 arranged in parallel linearly may be formed. Alternatively, as in B, a coil C3 arranged linearly, bent on the right and arranged linearly may be included. Alternatively, as in C, a coil C4 arranged to be repeatedly bent up and down may be included. Alternatively, as in D, a coil C5 repeatedly arranged in a tilted manner in one direction may be included. Alternatively, as in E, a coil C6 repeatedly arranged to be inclined in one direction, bent to the right and repeatedly arranged to be tilted in the opposite direction may be included. Alternatively, as in F, a coil C7 repeatedly arranged in an X-shape may be included. As described above, a coil portion C including various types of coils C1, C2, C3, C4, C5, C6, and C7 may be applied to the above-described printed circuit boards 100A, 100B, 100C, and 100D, but an example embodiment thereof is not limited thereto. Other descriptions may be substantially the same as the descriptions of the cross-sectional shape of the printed circuit boards 100A, 100B, 100C, 100D and the coil portion C described above, and accordingly, overlapping descriptions may not be provided.

According to the aforementioned example embodiments, a printed circuit board which may implement size reduction and may increase integration density may be provided.

Also, a printed circuit board which may increase power efficiency may be provided.

Also, a printed circuit board which may increase a noise reduction effect may be provided.

In the present disclosure, the term “covering” may include the configuration in which the component is entirely covered and at least a portion of the component is covered, or the component is directly or indirectly covered. Also, the term “fill” may include the configuration in which the component is completely filled, and also at least a portion of the component is filled, and the component is almost filled. For example, a void may be present. Also, the term “surrounding” may include the configuration in which the component is completely surrounded, and is also almost surrounded. Also, the term “exposing” may include the configuration in which the component is completely exposed or a portion thereof is exposed, and the exposing may refer to exposing from the buried component. For example, the configuration in which the opening may expose a pad may include exposing a pad from the resist layer, and a surface treatment layer may be further disposed on the exposed pad.

In the example embodiment, the configuration in which the component is disposed in a through-portion or a through-hole may include the configuration in which the component is completely disposed in the through-portion or through-hole, and also the configuration in which the component partially protrudes to an upper side or a lower side on a cross-section. For example, in the case in which the component is disposed in a through-portion or through-hole on a plane, the configuration may be understood in a broader sense.

In the present disclosure, the example embodiments may include process errors, positional deviations, and measurement errors occurring in the process. For example, the configuration in which components are substantially perpendicular to each other may include the example in which the components are completely perpendicular to each other, and also the example in which the components are almost perpendicular to each other. Also, the configuration in which the components are substantially coplanar with each other may include the example in which the components completely on the same plane, but also the example in which the components are almost on the same plane.

The notion of the same insulating material may indicate that the insulating materials are exactly the same but also the material may include the same type of insulating material. Accordingly, the composition of the insulating materials may be substantially the same, but specific composition ratios thereof may differ slightly.

In the present disclosure, the term “cross-section” refers to the cross-sectional shape when the object is cut vertically, or the cross-sectional shape when the object is cut vertically, or the cross-sectional shape when the object is viewed from the side. Also, the configuration in which the components are on a plane may indicate a planar shape when the object is cut horizontally, or a planar shape when the object is viewed from above or below.

In the present disclosure, the terms “lower side,” “lower portion,” and “lower surface” may be used to refer to a downward direction based on the cross-section of the drawing, and “upper side,” “upper portion,” “upper surface” may be used to refer to the opposite direction. However, this direction is defined for ease of description, and the scope of the patent claims is not particularly limited by the description of the direction, and the terms “upper and lower sides” may be relative terms.

In the example embodiments, the term “connected” may not only refer to “directly connected” but also include “indirectly connected” by may refer to of an adhesive layer, or the like. Also, the term “electrically connected” may include both of the case in which elements are “physically connected” and the case in which elements are “not physically connected.” Further, the terms “first,” “second,” and the like may be used to distinguish one element from the other, and may not limit a sequence and/or an importance, or others, in relation to the elements. In some cases, a first element may be referred to as a second element, and similarly, a second element may be referred to as a first element without departing from the scope of right of the example embodiments.

In the example embodiments, the term “example embodiment” may not refer to one same example embodiment, and may be provided to describe and emphasize different unique features of each example embodiment. The above suggested example embodiments may be implemented do not exclude the possibilities of combination with features of other example embodiments. For example, even though the features described in an example embodiment are not described in the other example embodiment, the description may be understood as relevant to the other example embodiment unless otherwise indicated.

An expression used in the singular encompasses the expression of the plural, unless it has a clearly different meaning in the context.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a substrate;
first and second through-portions penetrating between upper and lower surfaces of the substrate;
a magnetic layer disposed in the first through-portion;
a voltage regulator disposed in the second through-portion;
a first through-hole penetrating between upper and lower surfaces of the magnetic layer;
a first insulating layer disposed on the substrate, covering the magnetic layer and the voltage regulator, and filling at least a portion of each of the second through-portion and the first through-hole;
a second through-hole penetrating between upper and lower surfaces of the first insulating layer in the first through-hole;
a first wiring pattern disposed on an upper surface of the magnetic layer;
a second wiring pattern disposed on a lower surface of the magnetic layer; and
a first via pattern disposed in the second through-hole and connecting the first and second wiring patterns to each other.

2. The printed circuit board of claim 1,
wherein the first via pattern is disposed on a wall surface of the second through-hole, and
wherein the printed circuit board further includes a first filler filling a space between the first via pattern in the second through-hole.

3. The printed circuit board of claim 1, further comprising:
a first wiring layer disposed on an upper surface of the first insulating layer; and
a second wiring layer disposed on a lower surface of the first insulating layer,
wherein the first insulating layer is disposed between the first and second wiring patterns and upper and lower surfaces of the magnetic layer, and
wherein the first and second wiring layers include the first and second wiring patterns, respectively.

4. The printed circuit board of claim 3, further comprising:
a third through-hole penetrating between upper and lower surfaces of the substrate and filled at least partially with the first insulating layer;
a fourth through-hole penetrating between upper and lower surfaces of the first insulating layer in the third through-hole; and
a second via pattern disposed in the fourth through-hole and connecting the first and second wiring layers to each other.

5. The printed circuit board of claim 4,
wherein the second via pattern is disposed on a wall surface of the fourth through-hole, and
wherein the printed circuit board further includes a second filler filling a space between the second via pattern in the fourth through-hole.

6. The printed circuit board of claim 3, further comprising:
a first via layer penetrating an upper side of the first insulating layer and including a first connection via connecting the first wiring layer and the voltage regulator to each other,
wherein the voltage regulator and the first via pattern are connected to each other through a path passing through the first connection via and the first wiring layer.

7. The printed circuit board of claim 6, further comprising:
a second via layer penetrating a lower side of the first insulating layer and including a second connection via connecting the second wiring layer to the voltage regulator;
wherein the second connection via is connected to a back surface of the voltage regulator, and
wherein the first and second connection vias are tapered in opposite directions.

8. The printed circuit board of claim 3, further comprising:
a second insulating layer disposed on an upper surface of the first insulating layer;
a third insulating layer disposed on a lower surface of the first insulating layer;
a third wiring layer disposed on an upper surface of the second insulating layer;
a fourth wiring layer disposed on a lower surface of the third insulating layer;
a third via layer penetrating the second insulating layer and including a third connection via connecting the first and third wiring layers to each other; and
a fourth via layer penetrating the third insulating layer and including a fourth connection via connecting the second and fourth wiring layers to each other,
wherein the third and fourth connection vias are tapered in opposite directions.

9. The printed circuit board of claim 8, further comprising:
a first resist layer disposed on an upper surface of the second insulating layer and having a first opening exposing the third wiring layer; and
a second resist layer disposed on a lower surface of the third insulating layer and having a second opening exposing the fourth wiring layer.

10. The printed circuit board of claim 1, further comprising:
an integrated passive device disposed in the second through-portion,
wherein the first insulating layer covers the integrated passive device.

11. The printed circuit board of claim 1, further comprising:
a third through-portion penetrating between upper and lower surfaces of the substrate; and
an integrated passive device disposed in the third through-portion,
wherein the first insulating layer covers the integrated passive device and fills the third through-portion.

12. The printed circuit board of claim 1,
wherein the magnetic layer is spaced apart from a wall surface of the first through-portion, and
wherein the first insulating layer fills the first through-portion,

13. The printed circuit board of claim 1, wherein the magnetic layer is in contact with a wall surface of the first through-portion.

14. The printed circuit board of claim 1, wherein the substrate includes an organic core layer, a glass core layer, a metal core layer, a silicon core layer, or a ceramic core layer.

15. The printed circuit board of claim 1, wherein the first and second wiring pattern and the first via pattern are connected to each other to surround at least a portion of the magnetic layer to form an inductor that is disposed on the substrate.

16. A printed circuit board, comprising:
a substrate having a through-portion;
a magnetic layer spaced apart from the substrate in the through-portion and having a plurality of through-holes;
an insulating layer covering the substrate and the magnetic layer, at least partially filling a space between a wall surface of the through-portion and a side surface of the magnetic layer, and at least partially filling each of the plurality of through-holes;
a first wiring pattern layer disposed on an upper surface of the insulating layer;
a second wiring pattern layer disposed on a lower surface of the insulating layer; and
a plurality of via patterns penetrating the insulating layer in the plurality of through-holes.

17. The printed circuit board of claim 16,
wherein the first wiring pattern layer includes a plurality of first wiring patterns,
wherein the second wiring pattern layer includes a plurality of second wiring patterns, and
wherein the printed circuit board further includes a coil portion in which the plurality of first and second wiring patterns and the plurality of via patterns are alternately connected to each other.

18. The printed circuit board of claim 16, further comprising a second through-portion in which an integrated circuit chip is disposed.

19. The printed circuit board of claim 18, wherein at least a portion of the second through-portion is filled with the insulating layer.

20. A printed circuit board, comprising:
a substrate having a first through-portion and a second through-portion spaced apart from each other;
a magnetic layer disposed in the first through-portion;
an inductor disposed in the magnetic layer, the inductor comprising:
a first wiring pattern disposed on an upper surface of the magnetic layer,
a second wiring pattern disposed on a lower surface of the magnetic layer,
pattern vias penetrating the magnetic layer and connecting the first and second wiring patterns to form the inductor;
an integrated circuit chip disposed on the second through-portion; and
an insulating layer disposed on the substrate and at least partially filling the first through-portion and the second through-portion.

21. The printed circuit board of claim 20, wherein the integrated circuit chip comprises a voltage regulator.

22. The printed circuit board of claim 20, further comprising:
a third through-portion; and
an integrated passive device disposed in the third through-portion,
wherein the insulating layer covers the integrated passive device and fills the third through-portion.

23. The printed circuit board of claim 20,
wherein the magnetic layer is spaced apart from a wall surface of the first through-portion, and
wherein the insulating layer fills the first through-portion,

24. The printed circuit board of claim 20, wherein the magnetic layer is in contact with a wall surface of the first through-portion.
